(19) United States
(12) Patent Application Publication
(10) Pub. No.: US 2023/0098562 A1
(43) Pub. Date: Mar. 30, 2023

(54) PHASE CHANGE MEMORY CELL SIDEWALL PROJECTION LINER

(71) Applicant: International Business Machines Corporation, Armonk, NY (US)

(72) Inventors: Kevin W. Brew, Niskayuna, NY (US); Timothy Mathew Philip, Albany, NY (US); Andrew Herbert Simon, Fishkill, NY (US); Matthew T. Shoudy, Guilderland, NY (US); Injo Ok, Loudonville, NY (US)

(21) Appl. No.: 17/489,602

(22) Filed: Sep. 29, 2021

(51) Int. Cl. H01L 45/00

(52) U.S. Cl. CPC H01L 45/126; H01L 45/06; H01L 45/16

(57) ABSTRACT

A phase change memory (PCM) cell having a mushroom configuration includes a first electrode, a heater electrically connected to the first electrode, a first projection liner electrically connected to the heater, a PCM material electrically connected to the first projection liner, a second electrode electrically connected to the PCM material, and a second projection liner electrically connected to the first projection liner and the second electrode.

### BACKGROUND

The present invention relates to computer memory, and more specifically, to phase change material memory devices with projection liners.

Phase change memory (PCM) can be utilized for both training and inference in analog computing for artificial intelligence. The PCM structures can include phase change memristive devices with tunable conductivities and overall high device resistance with high retention to minimize energy consumption. The tuning can be accomplished by forming different structural states with varying proportions of crystalline and amorphous phases of PCM material. However, PCM materials can suffer from resistance drift, which can negatively affect the fidelity of the tuning.

### SUMMARY

According to an embodiment of the present disclosure, a PCM cell having a mushroom configuration includes a first electrode, a heater electrically connected to the first electrode, a first projection liner electrically connected to the heater, a PCM material electrically connected to the first projection liner, a second electrode electrically connected to the PCM material, and a second projection liner electrically connected to the first projection liner and the second electrode.

According to an embodiment of the present disclosure, a PCM cell includes a first electrode, a first projection liner electrically connected to the first electrode (the first projection liner comprising a first material), a PCM material electrically connected to the first projection liner, a second electrode electrically connected to the PCM material, and a second projection liner electrically connected to the first projection liner and the second electrode (the second projection liner comprising a second material), wherein the second material is different from the first material.

According to an embodiment of the present disclosure, a method of manufacturing a PCM cell includes forming a first electrode, forming a first projection liner electrically connected to the first electrode, forming a PCM material on the first projection liner, forming a second electrode on the PCM material, and forming a second projection liner (on the first projection liner, the PCM material, and the second electrode).

### BRIEF DESCRIPTION OF THE DRAWINGS

FIG. 1A is a cross-section view of a PCM cell including a sidewall projection liner, in accordance with an embodiment of the present disclosure.

FIG. 1B is a cross-section view of the PCM cell of FIG. 1A including a smaller amorphous zone, in accordance with an embodiment of the present disclosure.

FIG. 1C is a cross-section view of the PCM cell of FIG. 1A including a larger amorphous zone, in accordance with an embodiment of the present disclosure.

FIG. 2 is a flowchart of a method of manufacturing the PCM cell of FIG. 1A, in accordance with an embodiment of the present disclosure.

FIGS. 3A-3I are a series of cross-section views of the method of FIG. 2 of manufacturing the PCM cell, in accordance with an embodiment of the present disclosure.

FIG. 4A is a graph of resistance versus current for various liner electrical resistivity ratios of the PCM cell of FIG. 1A, in accordance with an embodiment of the present disclosure.

FIG. 4B is a graph of resistance versus current for various liner thickness ratios of the PCM cell of FIG. 1A, in accordance with an embodiment of the present disclosure.

### DETAILED DESCRIPTION

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layers “C” and “D”) are between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus. In addition, any numerical ranges included herein are inclusive of their boundaries unless explicitly stated otherwise.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

In general, the various processes used to form a micro-chip that will be packaged into an IC fall into four general categories, namely, film deposition, removal/etching, semiconductor doping and patterning/lithography.

Deposition can be any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Another deposition technology is plasma enhanced chemical vapor deposition (PECVD), which is a process which uses the energy within the plasma to induce reactions at the wafer surface that would otherwise require higher temperatures associated with conventional CVD. Energetic ion bombardment during PECVD deposition can also improve the film's electrical and mechanical properties.

Removal/etching can be any process that removes material from the wafer. Examples include etch processes (either wet or dry), chemical mechanical planarization (CMP), and the like. One example of a removal process is ion beam etching (IBE). In general, IBE (or milling) refers to a dry plasma etch method which utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry removal process is reactive ion etching (ME). In general, ME uses chemically reactive plasma to remove material deposited on wafers. With RIE the plasma is generated under low pressure (vacuum) by an electromagnetic field. High-energy ions from the ME plasma attack the wafer surface and react with it to remove material.

Semiconductor doping can be the modification of electrical properties by doping, for example, transistor sources and drains, generally by diffusion and/or by ion implantation. These doping processes are followed by furnace annealing or by rapid thermal annealing (“RTA”). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

Semiconductor lithography can be the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and gradually the conductors, insulators and selectively doped regions are built up to form the final device.

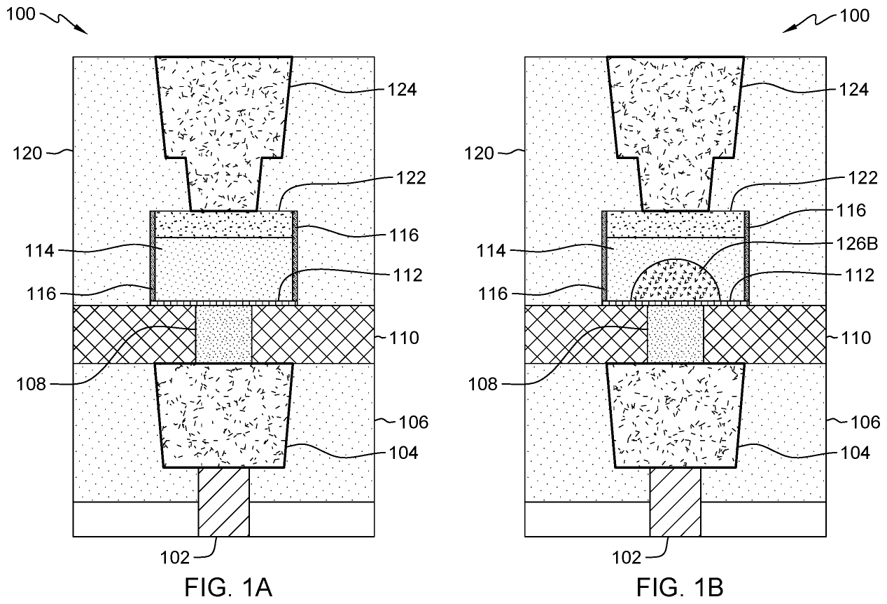

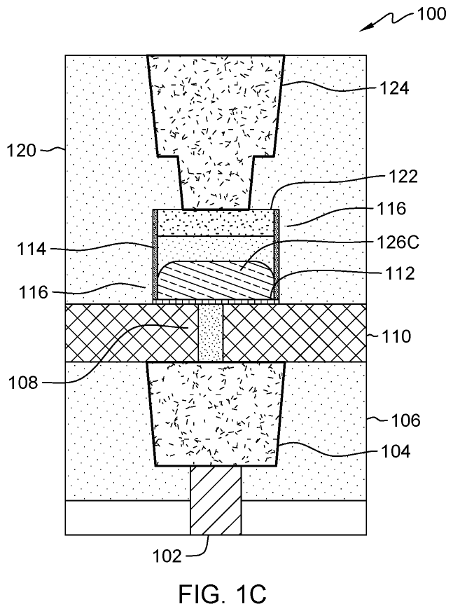

FIGS. 1A-1C are cross-section views of PCM cell 100 for use in, for example, an integrated circuit (not shown). In the illustrated embodiment, PCM cell 100 comprises bottom wire 102, bottom electrode 104, insulator 106, heater 108, insulator 110, bottom projection liner (PL) 112, PCM material 114, sidewall PL 116, insulator 120, top electrode 122, and top wire 124.

In the illustrated embodiment, the bottom of bottom electrode 104 is in direct contact with and electrically connected to the top of bottom wire 102, which can receive electrical signals from other components (not shown) of the integrated circuit. The bottom of heater 108 is in direct contact with and electrically connected to the top of bottom electrode 104. The bottom of bottom PL 112 is in direct contact with and electrically and thermally connected to the top of heater 108. The bottom of PCM material 114 is in direct contact with and electrically and thermally connected to the top of bottom PL 112. The bottom of top electrode 122 is in direct contact with and electrically connected to the top of PCM material 114. The bottom of top wire 124 is in direct contact with and electrically connected to the top of top electrode 122, and top wire 124 can deliver electrical signals from PCM cell 100 to other components (not shown) of the integrated circuit.

In the illustrated embodiment, the bottom of sidewall PL 116 is in direct contact with and electrically and thermally connected to the top of bottom PL 112. Furthermore, the inside of sidewall PL 116 is in direct contact with and electrically and thermally connected to the outer side of PCM material 114, so sidewall PL 116 laterally surrounds the outer side of PCM material 114. Thereby, sidewall PL 116 encloses PCM material 114 on all parallel sides in one direction for their entire longitudinal lengths (e.g., the sides that extend vertically, as shown in FIG. 1A), and does so adjacent the end of PCM material 114 (e.g., the bottom that extends horizontally, as shown in FIG. 1A) that is covered by bottom PL 112. In the depicted embodiment, PCM material 114 has a cylindrical shape (e.g., as opposed to a prismatic shape), which means there is only a single lateral outer side to be surrounded. In addition, the inside of sidewall PL 116 is in direct contact with and electrically connected to the outer side of top electrode 122.

In the illustrated embodiment, insulators 106, 110, 120 structurally support and electrically isolate the other components of PCM cell 100, selectively, and fill in the space therebetween, as appropriate. Thus, the outer side of bottom electrode 104 is in direct contact with and laterally surrounded by insulator 106, and the outer side of heater 108 is in direct contact with and laterally surrounded by insulator 110. Furthermore, the bottom side of bottom PL 112 is in direct contact with and axially adjacent to insulator 110, and sidewall PL and top wire 124 are in direct contact with and laterally and axially adjacent to insulator 120.

In the illustrated embodiment, a cross-section of PCM cell 100 (into the page in FIG. 1) can be circular, although in other embodiments, it can be rectangular, square, oval, or any other suitable shape. In addition, the widths of PCM material 114, bottom PL 112, and top electrode 122 are the same, whereas the width of heater 108 is substantially reduced, comparatively (e.g., three to seven times smaller, or about five times smaller). Thereby, PCM cell 100 can be said to have a mushroom configuration wherein an electrical signal (i.e., electrical current) can flow from bottom electrode 104 to top electrode 122 through heater 108, bottom PL 112, and PCM material 114.

In the illustrated embodiment, bottom electrode 104 and top electrode 122 are comprised of a very electrically conductive material, such as metal or metallic compound, for example, titanium nitride (TiN) or tungsten (W). Heater 108 is an electrode that is comprised of TiN or a higher resistance metal, such as, for example, titanium tungsten (TiW), tantalum nitride (TaN), or titanium aluminide (TiAl), and has a relatively narrow cross-sectional area, which focuses electrical current that is run through PCM cell 100. This allows heater 108 to generate heat through resistive heating during a pulse of electricity, which can be used to selectively change the temperature of PCM material 114, for example, above the crystallization temperature and the melting temperature of PCM material 114. In addition, heater 108 can be comprised of multiple different electrically conductive materials that can be arranged in multiple layers.

In the illustrated embodiment, insulators 106, 110, 120 are comprised of a dielectric (electrical insulating) material, such as, for example, silicon nitride (SiN), silicon oxide (SiO₂), silicon nitride carbide (SiNC), or tetraethyl orthosilicate (TEOS). In some embodiments, all of the insulators 106, 110, 120 are the same material, and in other embodiments, different materials are used for some or all of insulators 106, 110, 120. In addition, bottom PL 112 and sidewall PL 116 are comprised of a moderately electrically resistive material, such as a metal and/or semiconductor (e.g., TaN; tungsten nitride (WN); amorphous carbons (a-C); doped a-C; transparent conductive oxides such as tin-doped indium oxide (ITO), aluminum zirconium oxide (AZO), and high-resistance metal chalcogenides (ex. titanium selenide (TiSe)), and other poorly conducting metal nitrides). The materials comprising bottom PL 112 and sidewall PL 116 can be the same or they can be different. In addition, the materials comprising bottom PL 112 and sidewall PL 116 have a higher electrical resistivity than a polycrystalline phase of PCM material 114 but lower electrical resistivity than an amorphous phase of PCM material 114.

In the illustrated embodiment, PCM material 114 is composed essentially of a phase change material such as a germanium-antimony-tellurium (GST), gallium-antimony-tellurium (GaST), or silver-iridium-antimony-telluride (AIST) material, although other materials can be used as appropriate. Examples of other PCM materials can include, but are not limited to, germanium-tellurium compound material (GeTe), silicon-antimony-tellurium (Si—Sb—Te) alloys, gallium-antimony-tellurium (Ga—Sb—Te) alloys, germanium-bismuth-tellurium (Ge—Bi—Te) alloys, indium-tellurium (In—Se) alloys, arsenic-antimony-tellurium (As—Sb—Te) alloys, silver-indium-antimony-tellurium (Ag—In—Sb—Te) alloys, Ge—In—Sb—Te alloys, Ge—Sb alloys, Sb—Te alloys, Si—Sb alloys, Ge—Te alloys and combinations thereof. PCM material 114 may be undoped or doped (e.g., doped with one or more of oxygen (O), nitrogen (N), silicon (Si), or Ti). The terms “composed essentially” and “consist essentially,” as used herein with respect to materials of different layers, indicates that other materials, if present, do not materially alter the basic characteristics of the recited materials. For example, a PCM material 114 consisting essentially of GST material does not include other materials that materially alter the basic characteristics of the GST material.

In the illustrated embodiment, PCM cell 100 can be operated as a memory cell by passing an electrical current pulse from bottom electrode 104 to top electrode 122 to program PCM cell 100. This can be done at a variety of voltages and/or for a variety of durations to read or write a value on PCM cell 100. For example, to write, a high voltage can be used (e.g., 1 volt (V) to 4 V) for a short duration, which can cause heater 108 to locally heat PCM material 114 beyond its melting point. Once the flow of current ceases, PCM material 114 can cool down rapidly, which forms amorphous zone 126 in a process called “resetting”. Zone 126 is a dome-shaped region of PCM material 114 having an amorphous configuration, although the remainder of PCM material 114 is still in a polycrystalline configuration (labeled “126B” in FIG. 1B and “126C” in FIG. 1C). In general, this amorphous configuration has no definite structure. However, there can be local, disjoint crystalline nuclei (i.e., small, crystallized regions of phase change material 114) present in zone 126. The creation of zone 126 can cause the electrical resistance across PCM cell 100 to increase as compared to a solely polycrystalline configuration (a la PCM cell 100 in FIG. 1A). These resistance values of PCM cell 100 can be read without changing the state of PCM material 114 (including that of zone 126) or the resistance value of PCM cell 100, for example, by sending a current pulse at a low voltage (e.g., 0.2 V) from bottom electrode 104 to top electrode 122.

In addition, PCM material 114 can be rewritten and returned back to a solely polycrystalline configuration by “setting” PCM cell 100. One way to rewrite PCM material 114 uses a high voltage electrical pulse (e.g., 1 V to 4 V) for a short period of time (e.g., 10 nanoseconds (ns)), which can cause PCM material 114 to heat up beyond its crystallization point but not to its melting point. Since the crystallization temperature is lower than the melting temperature, once the flow of current ceases, PCM material 114 can anneal and form crystals. Another way to rewrite PCM material 114 uses an electrical pulse with a relatively long trailing edge (e.g., 1 microsecond) (as opposed to a square pulse with a relatively short trailing edge on the order of nanoseconds) that is strong enough to heat PCM material 114 beyond its melting point, after which, PCM material 114 is cooled down slowly, allowing crystals to form. Either of these processes cause the electrical resistance across PCM cell 100 to decrease as compared to having an amorphous zone 126. This new resistance value can then be read using current at a low voltage (e.g., 0.2 V) without changing the state of PCM material 114 or the resistance value of PCM cell 100.

In some embodiments, the melting temperature of PCM material 114 is about 600° C. In some embodiments, the crystallization temperature of PCM material 114 is about 180° C. In addition, the process of setting and resetting PCM cell 100 can occur repeatedly, and in some embodiments, different zones 126 with different resistances can be created in PCM materials 114 (e.g., due to having different sizes of zone 126 and/or amounts of crystallization nuclei in zone 126). This allows for PCM cell 100 to have various distinct resistances that can be created by varying the resetting parameters. Thereby, if PCM cell 100 is considered to represent information digits, these digits can be non-binary (as opposed to traditional bits). However, in some embodiments, PCM cell 100 can be used as a bit by either having or not having a uniform zone 126 in PCM material 114. In such embodiments, PCM cells 100 can have a high resistance (a.k.a., low voltage output or “0”) or low resistance (a.k.a., high voltage output or “1”).

The components and configuration of PCM cell 100 allow for an additional current path through PCM cell 100. Instead of current only traveling from bottom PL 112 to top electrode 122 via PCM material 114, current can also travel from bottom PL 112 to top electrode 122 via sidewall PL 116. As stated previously, sidewall PL 116 has an electrical resistivity between polycrystalline PCM material 114 and amorphous PCM material 114 (e.g., zone 126). Thereby, current can primarily pass through PCM material 114 if there is some in contact with bottom PL 112 (a la zone 126B), but current can primarily pass through at least a portion of sidewall PL 116 if zone 126 covers the entirety of bottom PL 112 (a la zone 126C).

Such capability can be beneficial given that PCM cell 100 can suffer from resistance drift of increasing resistance due to the intrinsic drift of amorphized PCM material (i.e., zone 126B). PCM cell 100 can also suffer from circuit noise which may be ameliorated by the incorporation of bottom PL 112 and sidewall PL 116. The issue of drift is further exacerbated by the scaling down of PCM cell 100 to small dimensions below about 60 nanometers (nm) where the amorphized volume of PCM material can span the entire lateral width of PCM material 114, forming zone 126C. If not for sidewall PL 116, zone 126C would result in the primary flow of electrical current traversing through amorphous PCM material, which would provide resistance drift in PCM cell 100. Whereas larger PCM cells may only have a bottom PL (since their amorphous zones would not cover the entire width of their PCM material), PCM cell 100 extends the benefits of bottom PL 112 up the sides of PCM material 114 using sidewall PL 116. These benefits can include reducing resistance drift, lowering the reading resistance (such that lower current pulses can be used to read PCM cell 100, which reduces the effect of the read pulses on zone 126), decreasing noise in readings, increasing control of heater 108, lowering the setting resistance, and increasing the dynamic range of PCM cell 100.

Depicted in FIGS. 1A-1C is one embodiment of the present disclosure, to which there are alternative embodiments. For example, PCM cell 100 can have a non-mushroom configuration, such as that of a confined cell. Such configurations may not have a separate heater, instead relying on the bottom electrode to tune the PCM material.

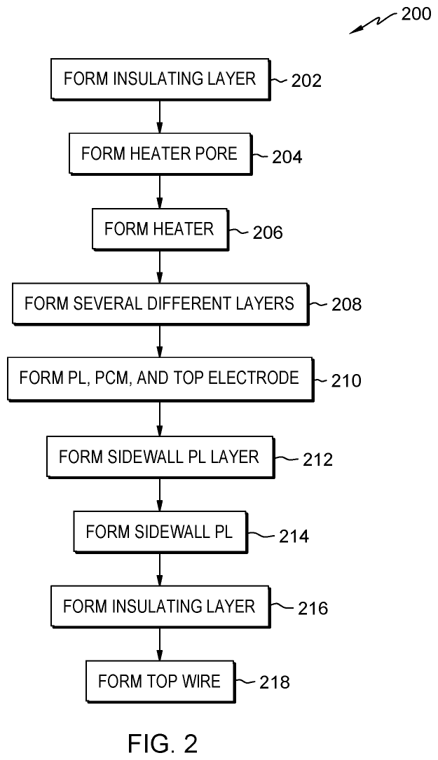

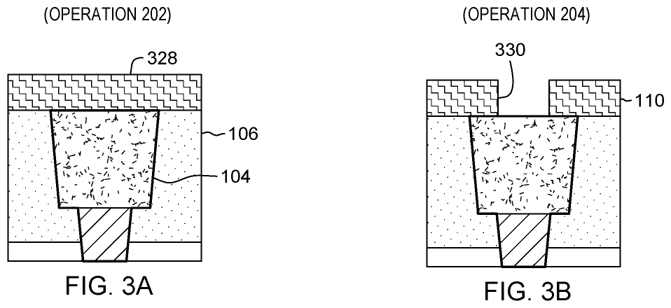

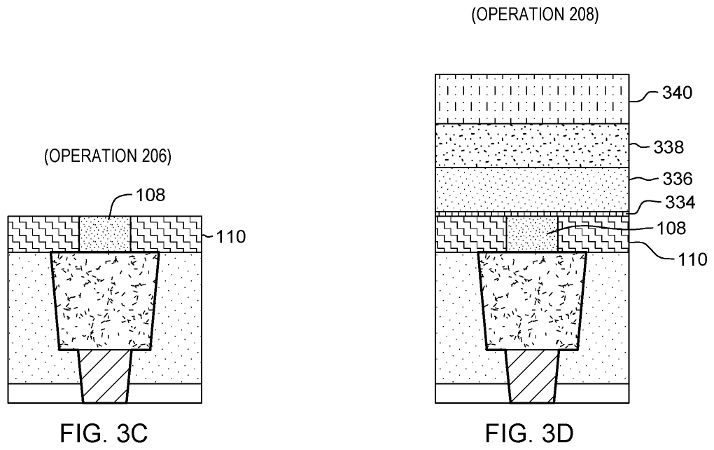

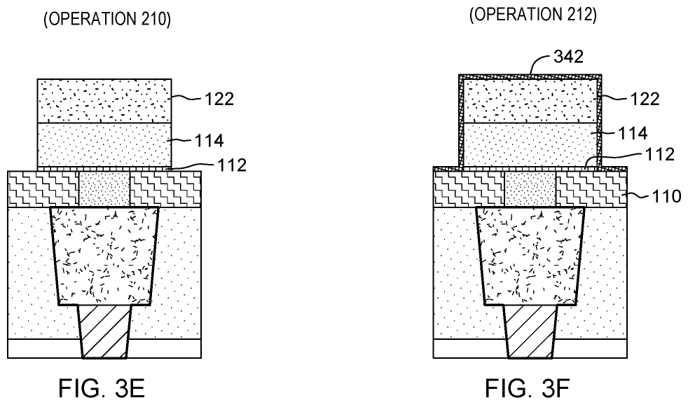

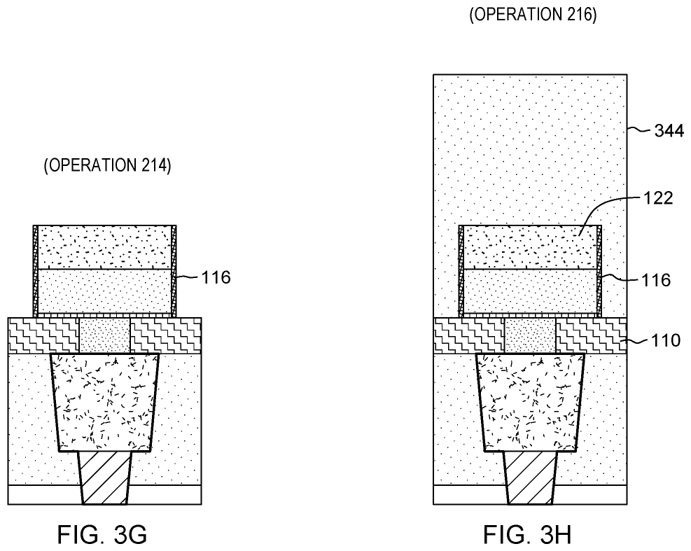

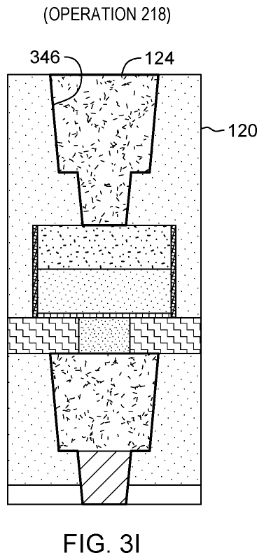

FIG. 2 is a flowchart of method 200 of manufacturing PCM cell 100. FIGS. 3A-3I are a series of views of method 200 of manufacturing PCM cell 100. FIGS. 2 and 3A-3I will now be discussed in conjunction with one another wherein each operation of method 200 is illustrated by one of FIGS. 3A-3I. In addition, during this discussion, references may be made to features of PCM cell 100 shown in FIGS. 1A-1C.

In the illustrated embodiment, method 200 starts at operation 202, wherein insulating layer 328 are formed on bottom electrode 104 and insulator 106. At operation 204, via 330 is formed in insulating layer 328, for example, using etching to form insulator 110. At operation 206, a heater layer (not shown) is formed on insulator 110, including in via 330 down to bottom electrode 104, and chemical mechanical polishing (CMP) is performed to remove the excess metal and form heater 108 coterminous with insulator 110. At operation 208, bottom PL layer 334 is formed on heater 108 and insulator 110. In addition, PCM layer 336, TiN layer 338, and SiN layer 340 are formed on bottom PL 112. In some embodiments, PCM layer 336 is about 80 nm thick, TiN layer 338 is about 75 nm thick, and SiN layer 340 is about 220 nm thick. At operation 210, masking and etching are performed to form bottom PL 112, PCM material 114, and top electrode 122.

In the illustrated embodiment, at operation 212, sidewall PL layer 342 is formed (e.g., using ALD) on insulator 110, bottom PL 112, PCM material 114, and top electrode 122. At operation 214, portions of sidewall PL layer 342 are selectively removed (e.g., using directional RIE or directional sputter etching) to form sidewall PL 116. At operation 216, insulator 110, sidewall PL 116, and top electrode 122 are encapsulated by forming insulating layer 344 thereon. At operation 218, pore 346 is formed in insulating layer 344 to form insulator 120, and top wire 124 is formed in pore 346 and on top electrode 122.

The components, configuration, and operation of PCM cell 100 and method 200 allow for sidewall PL 116 to be formed independently of bottom PL 112. This means that some or all of the parameters and properties (e.g., material, thickness, etc.) of sidewall PL 116 can be the same as or different from bottom PL 112, as desired. Changing such parameters/properties can result in differences between bottom PL 112 and sidewall PL 116 such as, for example, the electrical resistivity and/or electrical resistance thereof.

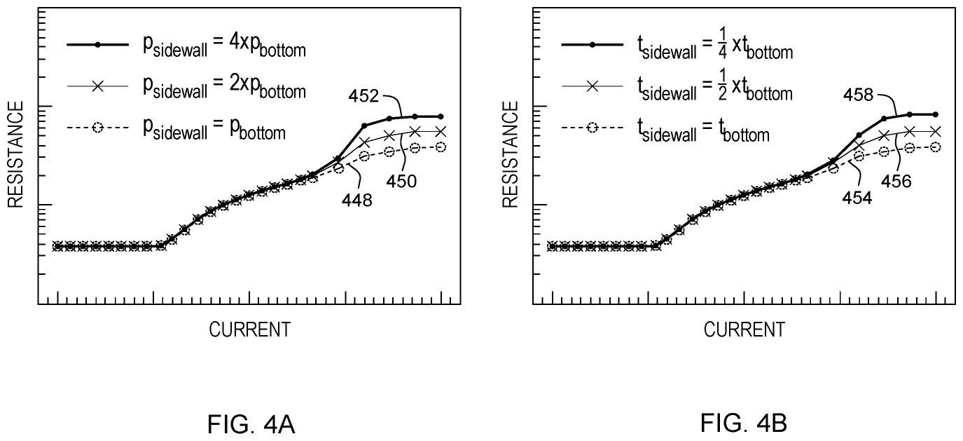

FIG. 4A is a graph of resistance versus current for various possible liner electrical resistivity ratios of PCM cell 100 (shown in FIG. 1A). Because resistance equals resistivity times length divided by area, the graph is made assuming that the dimensions of sidewall PL 116 and bottom PL 112 are held constant as their resistivity ratios are changed. FIG. 4A includes curve 448 representing a 1:1 ratio of resistivity of sidewall PL 116 (shown in FIG. 1A) versus resistivity of bottom PL 112 (shown in FIG. 1A), curve 450 representing a 2:1 ratio of resistivity of sidewall PL 116 versus resistivity of bottom PL 112, and curve 452 representing a 4:1 ratio of resistivity of sidewall PL 116 versus resistivity of bottom PL 112. In some embodiments, sidewall PL 116 can be an ALD film (e.g., for conformality) such as, for example AlN, TiN, or TaN, and bottom PL 112 can be a PVD film such as, for example, a-C or TaN. Then, the resistivities of sidewall PL 116 and bottom PL 112 can be tuned, for example, by doping, to achieve the ratios of curves 448, 450, and 452.

In the illustrated embodiment, current is displayed using a linear scale whereas resistance is displayed using a logarithmic scale. While it is not shown in the graph, if PCM cell 100 did not include sidewall PL 116 at all, then the resistance would be substantially higher at higher currents than curve 452 is. Furthermore, if the ratio of resistivity of sidewall PL 116 versus resistivity of bottom PL 112 was decreased below 1:1, then the resistance would be lower at higher currents than curve 448 is.

As indicated by the graph, increasing the relative resistivity of sidewall PL 116 allows for a higher dynamic range and resolution/contrast between tuning states given that zone 126C reaches the edges of PCM material 114 (shown in FIG. 1C). However, such a configuration can lead to increased resistance drift, so the different configurations (e.g., resistivity ratios) can be chosen based on their different advantages and disadvantages.

FIG. 4B is a graph of resistance versus current for various possible liner thickness ratios of PCM cell 100 (shown in FIG. 1A). Because resistance equals resistivity times length divided by area, this graph is made assuming that the resistivities, lengths, and diameters of sidewall PL 116 and bottom PL 112 are held constant as their thickness ratios are changed. FIG. 4B includes curve 454 representing a 1:1 ratio of thickness of sidewall PL 116 (shown in FIG. 1A) versus thickness of bottom PL 112 (shown in FIG. 1A), curve 456 representing a 1:2 ratio of thickness of sidewall PL 116 versus thickness of bottom PL 112, and curve 458 representing a 1:4 ratio of thickness of sidewall PL 116 versus thickness of bottom PL 112. In some embodiments, the thickness of sidewall PL 116 can be between 1 nm and 10 nm, and the thickness of bottom PL 112 can be between 1 nm and 5 nm. Thereby, for example, curve 454 can be achieved using a 4 nm thick sidewall PL 116 with a 4 nm thick bottom PL 112, curve 456 can be achieved using a 2 nm thick sidewall PL 116 with a 4 nm thick bottom PL 112, and curve 458 can be achieved using a 1 nm thick sidewall PL 116 with a 4 nm thick bottom PL 112.

In the illustrated embodiment, current is displayed using a linear scale whereas resistance is displayed using a logarithmic scale. While it is not shown in the graph, if PCM cell 100 did not include sidewall PL 116 at all, then the resistance would be substantially higher at higher currents than curve 458 is. Furthermore, if the ratio of thickness of sidewall PL 116 versus thickness of bottom PL 112 was increased above 1:1, then the resistance would be lower at higher currents than curve 454 is.

As indicated by the graph, increasing the relative thickness of sidewall PL 116 allows for a higher dynamic range and resolution/contrast between tuning states given that zone 126C reaches the edges of PCM material 114 (shown in FIG. 1C). However, such a configuration can lead to increased resistance drift, so the different configurations (e.g., thickness ratios) can be chosen based on their different advantages and disadvantages. Furthermore, changes to both thickness and electrical resistivity can be made to result in the appropriate electrical resistances for sidewall PL 116 and bottom PL 112 for a given configuration.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A phase change memory (PCM) cell having a mushroom configuration, the PCM cell comprising:
a first electrode;
a heater electrically connected to the first electrode;
a first projection liner electrically connected to the heater;
a PCM material electrically connected to the first projection liner;
a second electrode electrically connected to the PCM material; and
a second projection liner electrically connected to the first projection liner and the second electrode.

2. The PCM cell of claim 1, wherein:
the heater has a first width;
the PCM material has a second width; and
the second width is greater than or equal to thrice the first width.

3. The PCM cell of claim 2, wherein the second width is about five times greater than the first width.

4. The PCM cell of claim 1, wherein:
the first projection liner is comprised of a first material;
the second projection liner is comprised of a second material; and
the second material is different from the first material.

5. The PCM cell of claim 4, wherein:
the first material has a higher electrical resistivity than the PCM material in a polycrystalline phase and a lower electrical resistivity than the PCM material in an amorphous phase; and
the second material has a higher electrical resistivity than the PCM material in a polycrystalline phase and a lower electrical resistivity than the PCM material in an amorphous phase.

6. The PCM cell of claim 1, wherein:
the first projection liner extends along an end of the PCM material; and
the second projection liner extends along a side of the PCM material that is adjacent to the end.

7. The PCM cell of claim 6, wherein:
the first projection liner covers the end of the PCM material; and
the second projection liner encloses the side of the PCM material for its entire longitudinal length.

8. A phase change memory (PCM) cell comprising:
a first electrode;
a first projection liner electrically connected to the first electrode, the first projection liner comprising a first material;
a PCM material electrically connected to the first projection liner;
a second electrode electrically connected to the PCM material; and
a second projection liner electrically connected to the first projection liner and the second electrode, the second projection liner comprising a second material;
wherein the second material is different from the first material.

9. The PCM cell of claim 8, further comprising a heater electrically connected to the first electrode and the first projection liner.

10. The PCM cell of claim 9, wherein:
the heater has a first width;
the PCM material has a second width; and
the second width is greater than or equal to thrice the first width.

11. The PCM cell of claim 8, wherein:
the first projection liner covers an end of the PCM material; and
the second projection liner encloses a side of the PCM material, that is adjacent to the end, for its entire longitudinal length.

12. The PCM cell of claim 8, wherein:
the first material has a higher electrical resistivity than the PCM material in a polycrystalline phase and a lower electrical resistivity than the PCM material in an amorphous phase; and
the second material has a higher electrical resistivity than the PCM material in a polycrystalline phase and a lower electrical resistivity than the PCM material in an amorphous phase.

13. The PCM cell of claim 8, wherein:
the first material has a first electrical resistivity;
the second material has a second electrical resistivity; and
the second resistivity is greater than or equal to twice the first electrical resistivity.

14. The PCM cell of claim 8, wherein:
the first projection liner has a first thickness;
the second projection liner has a second thickness; and
the second thickness is less than or equal to half of the first thickness.

15. A method of manufacturing a phase change memory (PCM) cell, the method comprising:
forming a first electrode;
forming a first projection liner electrically connected to the first electrode;
forming a PCM material on the first projection liner;
forming a second electrode on the PCM material; and
forming a second projection liner on the first projection liner, the PCM material, and the second electrode.

16. The method of claim 15, further comprising forming a heater on the first electrode, wherein the first projection liner is formed on the heater.

17. The method of claim 16, wherein:
the heater has a first width;
the PCM material has a second width; and
the second width is greater than or equal to thrice the first width.

18. The method of claim 15, wherein:
the first projection liner is comprised of a first material;
the second projection liner is comprised of a second material; and
the second material is different from the first material.

19. The method of claim 18, wherein the second material has a higher electrical resistivity than the PCM material in a polycrystalline phase and a lower electrical resistivity than the PCM material in an amorphous phase.

20. The method of claim 19, wherein the first material has a higher electrical resistivity than the PCM material in a polycrystalline phase and a lower electrical resistivity than the PCM material in an amorphous phase.
